(19) United States
(12) Patent Application Publication
(10) Pub. No.: US 2008/0111254 A1
(43) Pub. Date: May 15, 2008

(54) PATTERN FILM, METHOD OF MANUFACTURING THE PATTERN FILM, AND PRINTED CIRCUIT BOARD AND SEMICONDUCTOR PACKAGE HAVING THE PATTERN FILM

(75) Inventors: Ji-Yong PARK, Gyeonggi-do (KR); Si-Hoon LEE, Gyeonggi-do (KR); Sang-Heui LEE, Chungcheongnam-do, (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/940,131

(22) Filed: Nov. 14, 2007

(30) Foreign Application Priority Data
Nov. 14, 2006 (KR) 2006-0112074

(51) Int. Cl. H01L 23/48; H05K 1/03; H05K 3/36

(52) U.S. Cl. 257/786; 174/258; 29/830; 257/E23.01

(57) ABSTRACT

A pattern film in accordance with one aspect of the present invention includes a first film and a second film. A first pattern array is built in the first film. The second film is attached to the first film. Further, a second pattern array is built in the second film. The second pattern array is partially overlapped with the first pattern array. The first and the second pattern arrays may be electrically connected to each other by a pressurizing process. Thus, a time and a cost for manufacturing the pattern film may be reduced. As a result, a printed circuit board and a semiconductor package having the pattern film may also be manufactured at a low expense.

### CROSS-REFERENCE TO RELATED APPLICATION

This application claims priority under 35 USC §119 to Korean Patent Application No. 2006-112074 filed on Nov. 14, 2006, the contents of which are herein incorporated by reference in their entirety.

### BACKGROUND

1. Field of Invention

Example embodiments of the present invention relate to a pattern film, a method of manufacturing the pattern film, and a printed circuit board and a semiconductor package having the pattern film. More particularly, example embodiments of the present invention relate to a pattern film having a conductive pattern, a method of manufacturing the pattern film, and a printed circuit board and a semiconductor package having the pattern film.

2. Description of the Related Art

Generally, various semiconductor processes may be carried out on a semiconductor substrate to form a plurality of semiconductor chips. To mount the semiconductor chips on a motherboard, a packaging process may be performed on the semiconductor substrate.

Particularly, the semiconductor chip is mounted on a printed circuit board (PCB). The semiconductor chip and the PCB are electrically connected to each other using a conductive bump, a conductive wire, etc. An outer terminal such as a solder ball is mounted on the PCB. Thus, the PCB has a conductive pattern for electrically connecting the semiconductor chip to the solder ball.

Conventional examples of a PCB having a conductive pattern are understood to be disclosed in Japanese Patent Laid-Open Publication Nos. 1995-312468, 1998-190164 and 2004-22984.

According to a conventional method of manufacturing a PCB having a conductive pattern, a thin copper layer is formed on a substrate. A photoresist pattern is then formed on the copper layer. The copper layer is etched using the photoresist pattern as an etching mask to form a copper layer pattern. The photoresist pattern is then removed. A solder resist film is formed on the substrate to expose the copper layer pattern through the solder resist film.

However, because the conventional method of manufacturing the PCB may include a plurality of processes, a cost for manufacturing the PCB may be undesirably high. Further, a plating process for forming the copper layer and a photolithography process for forming the copper layer pattern may require an undesirably long time and high cost.

### SUMMARY

Example embodiments described herein may be characterized as providing a pattern film that includes a structure having a desired pattern obtained by a simple process. Example embodiments described herein may also be characterized as providing a method of manufacturing such a pattern film. Other example embodiments described herein may be characterized as providing a printed circuit board having the above-mentioned pattern film. Still other example embodiments described herein may be characterized as providing a semiconductor package having the above-mentioned pattern film.

One example embodiment described herein may be generally characterized as a pattern film that includes a first film having a first pattern array and a second film having a second pattern array. The second film may be arranged on the first film such that the second pattern array is partially overlapped with the first pattern array.

Another example embodiment described herein may be generally characterized as a pattern film that includes a first film having first patterns arranged along lengthwise and widthwise directions and a second film arranged on the first film. The second film may have second patterns arranged along the lengthwise and widthwise directions. Each of the second patterns may be partially overlapped with at least two adjacent ones of the first patterns.

### BRIEF DESCRIPTION OF THE DRAWINGS

The above and other features and advantages of the embodiments exemplarily described herein will become readily apparent by reference to the following detailed description when considered in conjunction with the accompanying drawings wherein:

FIG. 1 is a plan view illustrating a pattern film in accordance with a first example embodiment;

FIG. 2 is a cross-sectional view taken along line II-II′ shown in FIG. 1;

FIGS. 3 to 9 are plan views and cross-sectional views illustrating an exemplary method of manufacturing the pattern film in FIG. 1;

FIG. 10 is a plan view illustrating a pattern film in accordance with a second example embodiment;

FIG. 11 is a plan view illustrating a pattern film in accordance with a third example embodiment;

FIG. 12 is a plan view illustrating a pattern film in accordance with a fourth example embodiment;

FIG. 13 is a plan view illustrating a pattern film in accordance with a fifth example embodiment;

FIG. 14 is a plan view illustrating a pattern film in accordance with a sixth example embodiment;

FIG. 15 is a plan view illustrating one embodiment of a printed circuit board; and

FIG. 16 is a plan view illustrating one embodiment of a semiconductor package.

### DETAILED DESCRIPTION

Example embodiments of the present invention are described more fully hereinafter with reference to the accompanying drawings. These embodiments may, however, be realized in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention as defined in the claims. As used herein, the singular forms “a,” “an” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

### EXAMPLE EMBODIMENT 1

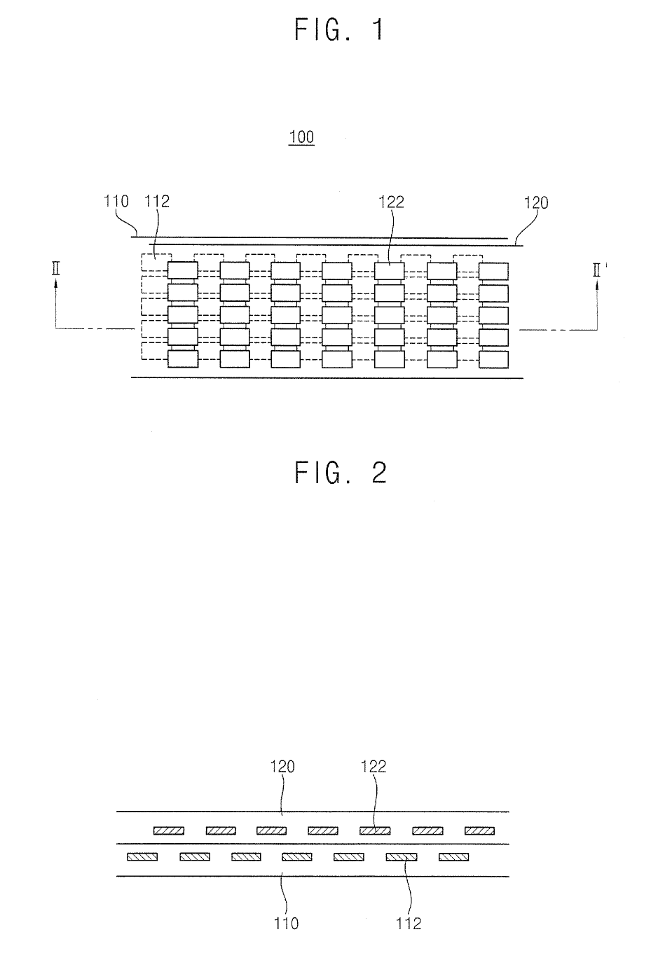

FIG. 1 is a plan view illustrating a pattern film in accordance with a first example embodiment. FIG. 2 is a cross-sectional view taken along line II-II′ shown in FIG. 1.

Referring to FIGS. 1 and 2, a pattern film 100 may, for example, include a first film 110 and a second film 120.

The first film 110 may include an insulation material. In one embodiment, the insulation material of the first film 110 may include a thermoplastic material that is capable of being ruptured by pressurization and/or heat. Accordingly, the first film 110 may be characterized as including a deformable insulation material. A first pattern array is provided in the first film 110. The first pattern array includes first patterns 112 arranged along lengthwise and widthwise directions. In one embodiment, the first patterns 112 comprise a conductive material.

In one embodiment, the first patterns 112 are arranged along lengthwise and widthwise directions. The first patterns 112 are spaced apart from each other along the lengthwise direction by a first lengthwise interval. The first patterns 112 are spaced apart from each other along the widthwise direction by a first widthwise interval. Thus, the first patterns 112 are electrically insulated from one another. In one embodiment, the first lengthwise interval and the first widthwise interval may be substantially same. In another embodiment, the first lengthwise interval and the first widthwise interval may be different from each other. In one embodiment, the first patterns 112 may have a substantially rectangular shape. In another embodiment, the first patterns 112 may have one or more polygonal shapes such as a triangular shape, a pentagonal shape, or the like, as well as the rectangular shape.

The second film 120 is attached to the first film 110. The second film 120 may include a material that is substantially the same as the material of the first film 120. For example, the second film 120 may include an insulation material that is capable of being ruptured by pressurization and/or heat. Accordingly, the second film 120 may be characterized as including a deformable insulation material. A second pattern array is provided in the second film 120. The second pattern array is partially overlapped with the first pattern array.

In one embodiment, the second pattern array includes second patterns 122 arranged along lengthwise and widthwise directions. In one embodiment, the first patterns 122 comprise a conductive material. The second patterns 122 are spaced apart from each other along the lengthwise direction by a second lengthwise interval. The second patterns 122 are spaced apart from each other along the widthwise direction by a second widthwise interval. Thus, the second patterns 122 are electrically insulated from one another. In one embodiment, the second lengthwise and second widthwise intervals may be substantially the same as the first lengthwise and first widthwise intervals. In another embodiment, the second lengthwise interval and the second widthwise interval between the second patterns 122 may be substantially same. In another embodiment, the second lengthwise interval and the second widthwise interval between the second patterns 122 may be different from each other. In one embodiment, the shape and size of the second patterns 122 may be substantially the same as the shape and size of the first patterns 112. In another embodiment, the second patterns 122 may have a polygonal shape such as a triangular shape, a pentagonal shape, or the like, as well as the rectangular shape.

As mentioned above, the second pattern array is partially overlapped with the first pattern array. Thus, each of the second patterns 122 is partially overlapped with four adjacent first patterns 112. That is, each of the second patterns 122 may be positioned at a central portion between four adjacent first patterns 112. In one embodiment, since the first patterns 112 and the second patterns 122 have a substantially rectangular shape, four corners of each of the second patterns 122 are partially overlapped with a corner of four adjacent first patterns 112. In one embodiment, each of the second patterns 122 can be characterized as being partially overlapped with two or more adjacent first patterns 112. Therefore, when the partially overlapped first and second patterns 112 and 122 are selectively connected to each other by a simple pressurizing process, adjacent ones of the first patterns 112, which are electrically isolated from each other by the insulation material of the first film 110, are electrically connected to each other by the second patterns 122. As a result, first and second patterns 112 and 122, when electrically connected together, may form a desired conductive pattern.

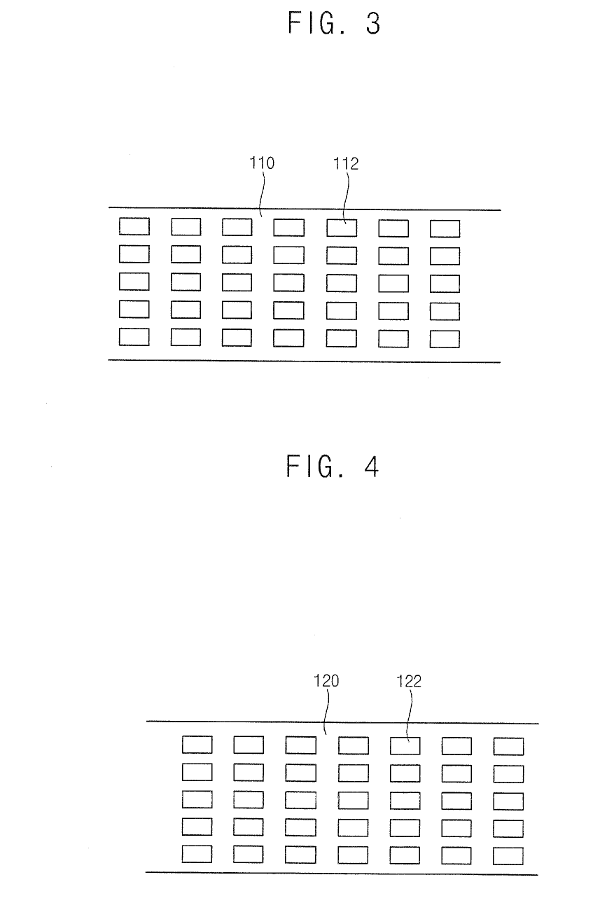

FIGS. 3 to 9 are plan views and cross-sectional views illustrating an exemplary method of manufacturing the pattern film shown in FIGS. 1 and 2.

Referring to FIG. 3, the first film 110 having the first pattern array is prepared. In one embodiment, the first pattern array includes the first patterns 112 arranged along the lengthwise direction so as to be spaced apart from each other by the first lengthwise interval and arranged along the widthwise direction so as to be spaced apart from each other by the first widthwise interval.

Referring to FIG. 4, the second film 120 having the second pattern array is prepared. In one embodiment, the second pattern array includes the second patterns 122 arranged along the lengthwise direction so as to be spaced apart from each other by the second lengthwise interval and arranged along the widthwise direction so as to be spaced apart from each other by the second widthwise interval. In the illustrated embodiment, the first patterns 112 and the second patterns 122 may have substantially the same size and shape.

Referring to FIG. 5, the second film 120 is attached to the first film 110. In one embodiment, the second film 120 is attached to the first film 110 such that the second pattern array is partially overlapped with the first pattern array. Thus, each of the second patterns 122 is positioned at a central region between four adjacent first patterns 112 such that four corners of each of the second patterns 122 are partially overlapped with corresponding corners of the first patterns 112. Although the first patterns 112 and the second patterns 122 are partially overlapped with each other, the insulation material of at least one of the first film 110 and the second film 120 is interposed between the first patterns 112 and the second patterns 122. In one embodiment, the insulation material of the first film 110 and the second film 120 is interposed between the first patterns 112 and the second patterns 122. As a result, the pattern film 100 shown in FIGS. 1 and 2, having the partially overlapped first and second patterns 112 and 122 which are not electrically connected to each other, is completed. To form a desired conductive pattern in the pattern film 100, the following processes are carried out on the pattern film 100.

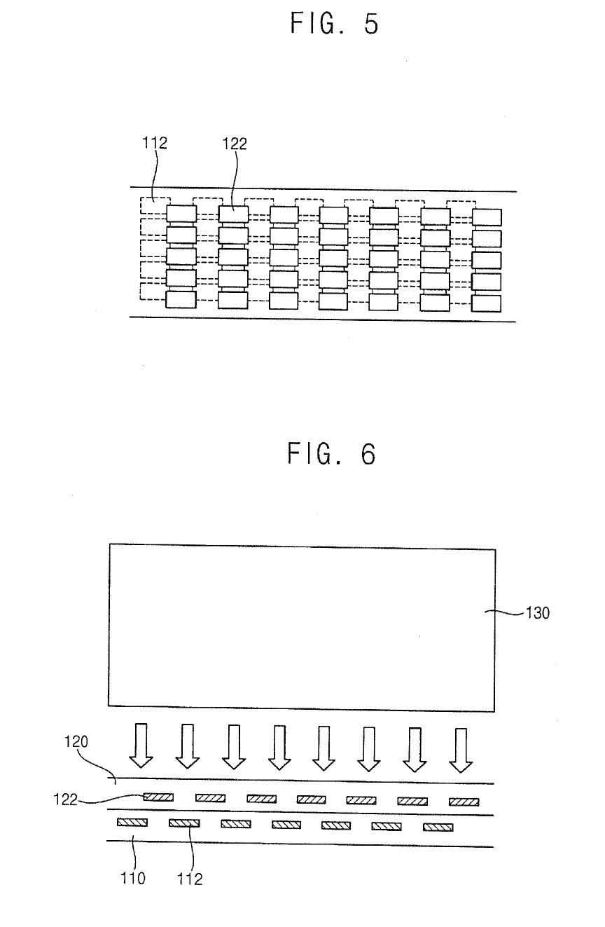

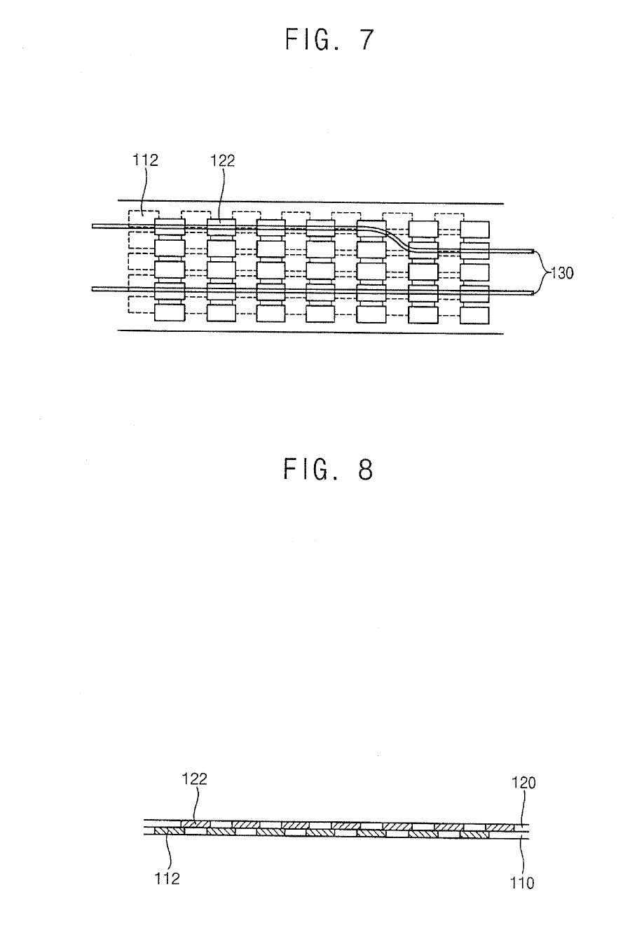

Referring to FIGS. 6 and 7, the second film 120 is pressurized using a pattern tool 130 that has a shape corresponding to the shape of the desired pattern. Portions of the first film 110 and the second film 120 that are pressurized by the pattern tool 130 can be ruptured. As a result, a portion of the second patterns 122, when pressurized by the pattern tool 130, are electrically connected to a portion of the first patterns 112 through the insulation material of the first film 110 and the second film 120 as shown in FIG. 8. Other portions of the second patterns 122 that are not pressurized by the pattern tool 130, however, remain electrically isolated from the first patterns 112 by the insulation material of the first film 110 and the second film 120 as shown in FIG. 2.

In another embodiment, each pressurized second pattern 122 may be electrically connected to two, three or four adjacent ones of the first patterns 112. It will be appreciated that the number of connections between adjacent ones of the first patterns 112 and the second patterns 122 may vary in accordance with the shape of the pattern tool 130. Thus, when the shape of the desired conductive pattern changes, the pattern film 100 is pressurized using a new pattern tool having a shape corresponding that of the desired conductive pattern. It will also be appreciated that the number of connections between adjacent ones of the first patterns 112 and the second patterns 122 may vary in accordance with number, size and shape of the first patterns 112 and/or second patterns 122.

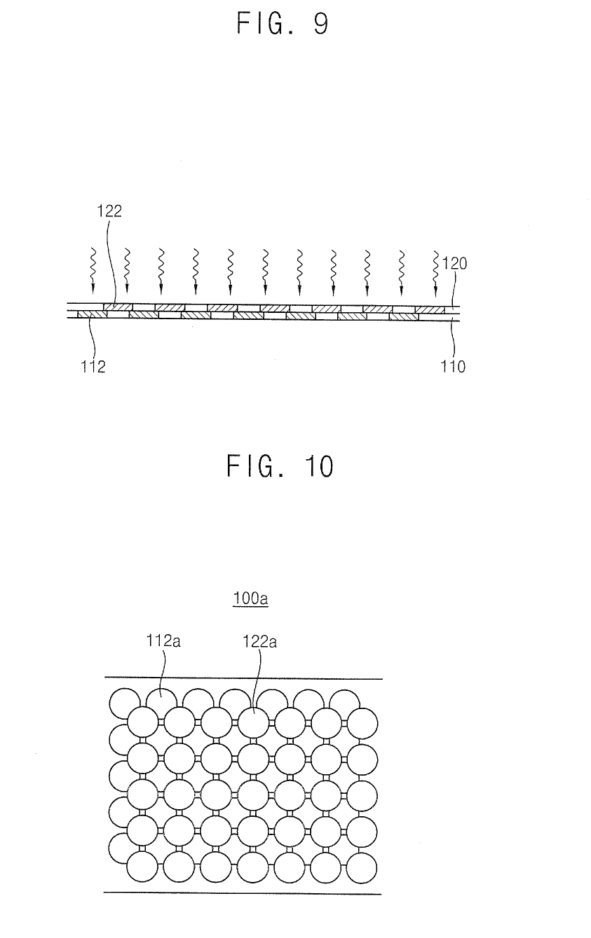

Referring to FIG. 9, the electrically connected first and second patterns 112 and 122 may be thermally cured to prevent the electrically connected first and second patterns 112 and 122 from being separated (e.g., due to an external impact).

### EXAMPLE EMBODIMENT 2

FIG. 10 is a plan view illustrating a pattern film in accordance with a second example embodiment.

Features of the pattern film 100a shown in FIG. 10 are substantially the same as corresponding features of the pattern film 100 shown in FIG. 1, except for shapes of the first and second patterns. Thus, the same reference numerals refer to the equivalent elements and any further description with respect to the same elements are omitted herein for brevity.

Referring to FIG. 10, the first patterns 112a and the second patterns 122a of the pattern film 100a may have a substantially circular shape. Thus, each of the substantially circular second patterns 122a may be partially overlapped with four adjacent first patterns 112a, which are also substantially circular.

### EXAMPLE EMBODIMENT 3

FIG. 11 is a plan view illustrating a pattern film in accordance with a third example embodiment.

Features of the pattern film 100b shown in FIG. 11 are substantially the same as corresponding features of the pattern film 100 shown in FIG. 1, except for shapes of the first and second patterns. Thus, the same reference numerals refer to the equivalent elements and any further description with respect to the same elements are omitted herein for brevity.

Referring to FIG. 11, the first patterns 112b and the second patterns 122b of the pattern film 100b may have an elliptical shape. Thus, each of the elliptical second patterns 122b may be partially overlapped with four adjacent first patterns 112b, which are also elliptical.

### EXAMPLE EMBODIMENT 4

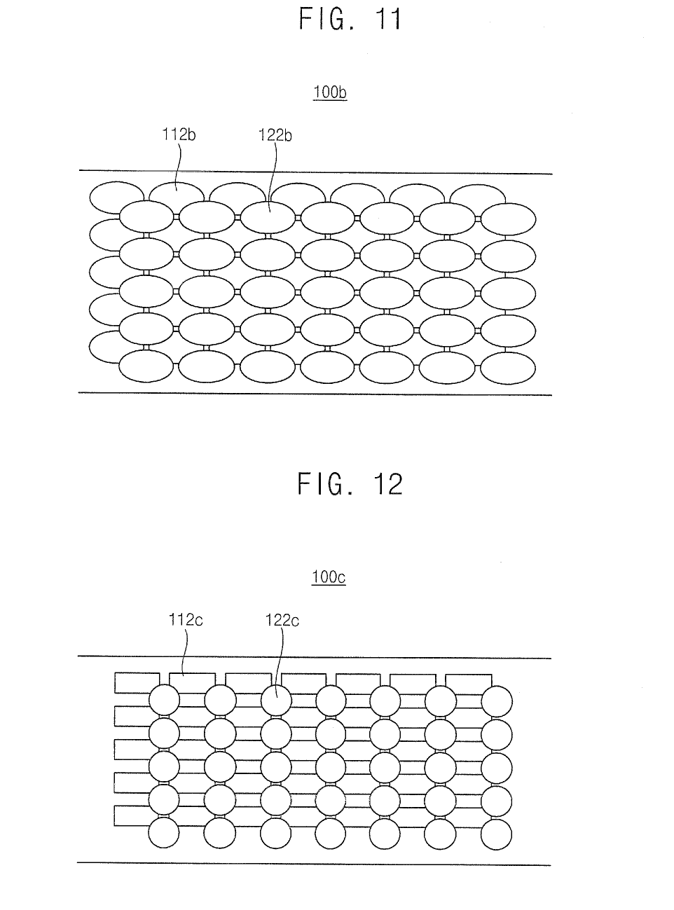

FIG. 12 is a plan view illustrating a pattern film in accordance with a fourth example embodiment.

Features of the pattern film 100c shown in FIG. 12 are substantially the same as corresponding features of the pattern film 100 shown in FIG. 1, except for shapes of the first and second patterns. Thus, the same reference numerals refer to the equivalent elements and any further description with respect to the same elements are omitted herein for brevity.

Referring to FIG. 12, the first patterns 112c of the pattern film 100c have a substantially rectangular shape and the second patterns 122c of the pattern film 100c have a substantially circular shape. Thus, each of the substantially circular second patterns 122c is partially overlapped with four adjacent substantially rectangular first patterns 112c. Alternatively, the first patterns 112c of the pattern film 100c may have a substantially circular shape and the second patterns 122c of the pattern film 100c may have a substantially rectangular shape.

### EXAMPLE EMBODIMENT 5

FIG. 13 is a plan view illustrating a pattern film in accordance with a fifth example embodiment.

Features of the pattern film 100d shown in FIG. 13 are substantially the same as corresponding features of the pattern film 100 shown in FIG. 1, except for shapes of the first and second patterns. Thus, the same reference numerals refer to the equivalent elements and any further description with respect to the same elements are omitted herein for brevity.

Referring to FIG. 13, the first patterns 112d of the pattern film 100d have a substantially rectangular shape and the second patterns 122d of the pattern film 100d have an elliptical shape. Thus, each of the substantially rectangular second patterns 122d is partially overlapped with four adjacent elliptical first patterns 112d. Alternatively, the first patterns 112d of the pattern film 100d may have an elliptical shape and the second patterns 122d of the pattern film 100d may have a substantially rectangular shape.

### EXAMPLE EMBODIMENT 6

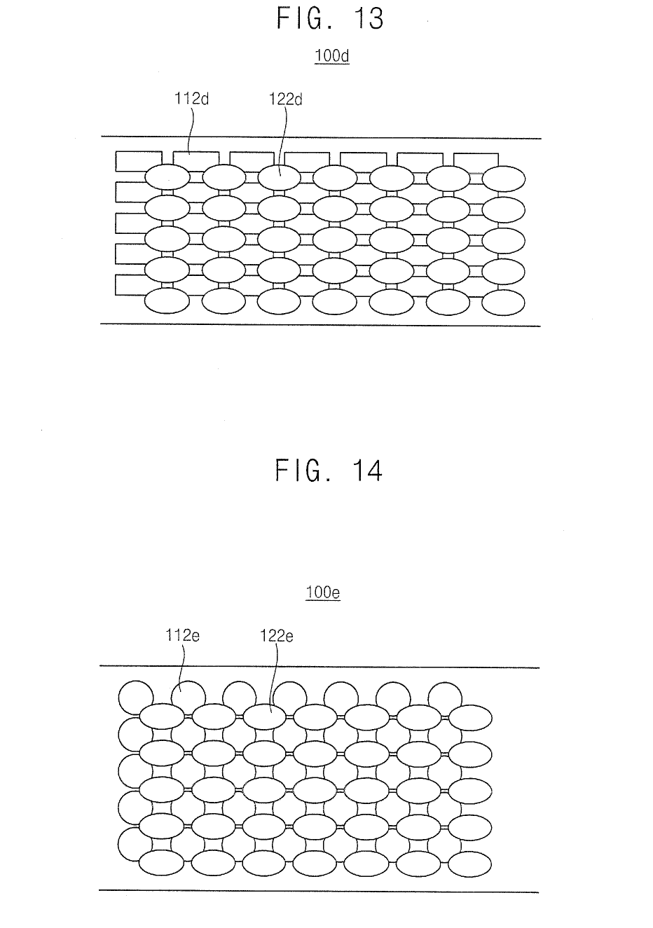

FIG. 14 is a plan view illustrating a pattern film in accordance with a sixth example embodiment.

Features of the pattern film 100e shown in FIG. 14 are substantially the same as corresponding features of the pattern film 100 shown in FIG. 1, except for shapes of the first and second patterns. Thus, the same reference numerals refer to the equivalent elements and any further description with respect to the same elements are omitted herein for brevity.

Referring to FIG. 14, the first patterns 112e of the pattern film 100e have a substantially circular shape and the second patterns 122e of the pattern film 100e have an elliptical shape. Thus, each of the substantially circular second patterns 122e is partially overlapped with four adjacent elliptical first patterns 112e. Alternatively, the first patterns 112e of the pattern film 100e may have an elliptical shape and the second patterns 122e of the pattern film 100e may have a substantially circular shape.

### EXAMPLE EMBODIMENT 7

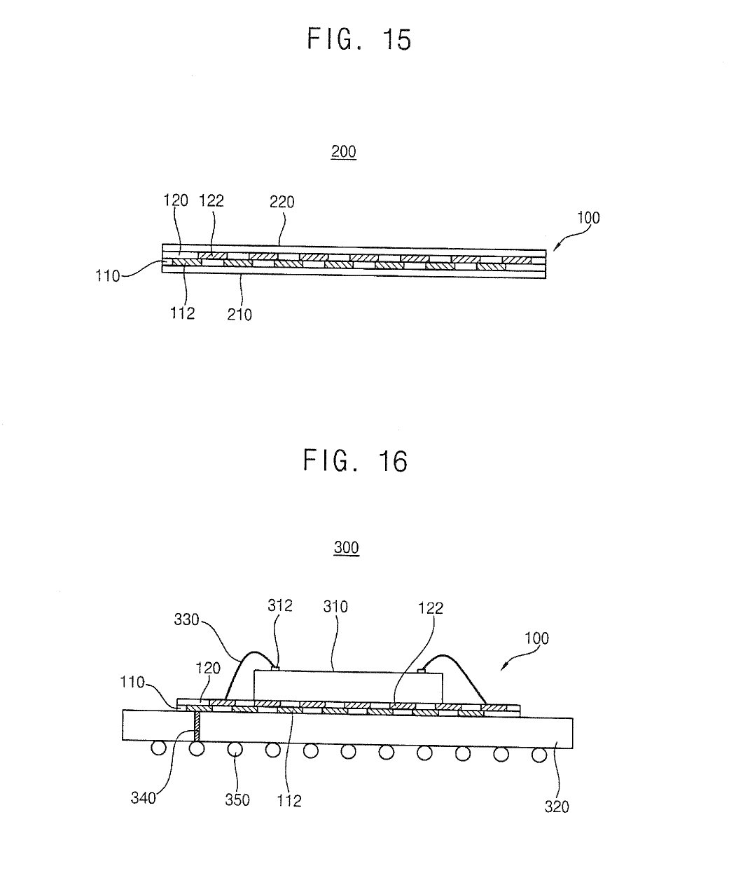

FIG. 15 is a cross-sectional view illustrating one embodiment of a printed circuit board.

Referring to FIG. 15, a printed circuit board (PCB) 200 may, for example, include a substrate 210, the pattern film 100 and an insulation layer pattern 220. The pattern film 100 shown in FIG. 15 may be provided as exemplarily described with respect to FIGS. 1 and 2. Thus, any further description with respect to the pattern film 100 will be omitted herein for brevity. It will be appreciated, however, that the pattern films 100a, 100b, 100c, 100d and 100e, each provided as exemplarily described with respect to FIGS. 10 through 14, may be incorporated in the PCB 200.

The pattern film 100 is attached to the substrate 210. In one embodiment, the first film 110 of the pattern film 100 is attached to the substrate 210. The insulation layer pattern 220 is formed on the second film 120 of the pattern film 100. In one embodiment, second patterns 122 of the second film 120 that are electrically connected to the first patterns 112 of the first film 110 may be exposed through the insulation layer pattern 200.

### EXAMPLE EMBODIMENT 8

FIG. 16 is a cross-sectional view illustrating one embodiment of a semiconductor package.

Referring to FIG. 16, a semiconductor package 300 may, for example, include a semiconductor chip 310, the pattern film 100, a substrate 320, a conductive wire 330, a conductive member 340 and outer terminals 350.

The pattern film 100 is interposed between the semiconductor chip 310 and the substrate 320. The pattern film 100 shown in FIG. 16 may be provided as exemplarily described with respect to FIGS. 1 and 2. Thus, any further description with respect to the pattern film 100 will be omitted herein for brevity. It will be appreciated, however, that the pattern films 100a, 100b, 100c, 100d and 100e, each provided as exemplarily described with respect to FIGS. 10 through 14, may be incorporated in the semiconductor package 300.

Pads 312 of the semiconductor chip 310 are electrically connected to the second patterns 122 of the pattern film 100 through the conductive wire 330. In one embodiment, the second patterns 122 are electrically connected to the first patterns 112. Alternatively, the pads 312 of the semiconductor chip 310 may be electrically connected to the second patterns 122 using a conductive bump (not shown).

A via hole is formed through the substrate 320. The via hole is filled with the conductive member 340. Thus, the conductive member 340 has an upper end electrically connected to the first pattern 112 and a lower end exposed through the substrate 320.

The outer terminals 350 are mounted on the exposed lower ends of the conductive member 340. In this example embodiment, the outer terminals 350 may include a solder ball.

Therefore, the pads 312 of the semiconductor chip 310 are electrically connected to the outer terminals 350 through the conductive wire 330, the second patterns 122, the first patterns 112 and the conductive member 340.

It will be appreciated that the pattern film 100 may be employed in other semiconductor packages having structures that are different from that of the semiconductor package explicitly shown.

According to the embodiments exemplarily described above, desired portions of the first and the second patterns may be electrically connected to each other by a simple pressurizing process. Thus, a desired pattern shape may be formed at a low expense and in a short amount of time. As a result, a cost and a time associated with manufacturing a PCB and a semiconductor package having the pattern film may be considerably reduced.

Example embodiments of the present invention will now be provided. It will be appreciated that the example embodiments which follow are not exhaustive. In one embodiment, a pattern film includes a first film and a second film. A first pattern array is built in the first film. The second film is attached on the first film. Further, a second pattern array is built in the second film. The second pattern array is partially overlapped with the first pattern array.

According to one example embodiment, the first pattern array may include first patterns arranged by a first interval. The second pattern array may include second patterns arranged by a second interval. Each of the second patterns may be partially overlapped with adjacent four first patterns. Further, the first patterns may be arranged along lengthwise and widthwise directions by the first interval. The second patterns may be arranged along lengthwise and widthwise directions by the second interval. Furthermore, the first patterns and the second patterns may have a substantially the same shape. Alternatively, the first patterns and the second patterns may have shapes different from each other.

According to another example embodiment, the first and the second films may include a thermoplastic film.

In a method of manufacturing a pattern film in accordance one embodiment, a first film and a second film are prepared. Here, a first pattern array is built in the first film. Further, a second pattern array is built in the second film. The second film is attached on the first film to partially overlap the second pattern array with the first pattern array. The second film is selectively pressurized to electrically connect desired portions of the first and the second pattern arrays to each other.

According to one example embodiment, the second film may be selectively pressurized using a pattern tool having a shape that corresponds to a desired pattern shape.

According to another example embodiment, the electrically connected first and second pattern arrays may be additionally thermally cured.

In another method of manufacturing a pattern film, a first film having a first pattern array may be prepared and a second film having a second pattern array may be prepared. The second film may be attached on the first film such that the second pattern array is partially overlapped with the first pattern array. The second film may be selectively pressurized to electrically connect desired portions of the first pattern array and the second pattern array to each other.

The second film may be selectively pressurized using a pattern tool that has a shape corresponding to that of a desired pattern. Moreover, the electrically connected first and second pattern arrays may be thermally cured. The first film and the second film may comprise a thermoplastic film.

A printed circuit board in accordance with still another embodiment includes a substrate, a pattern film and an insulation layer pattern. The pattern film is attached on the substrate. Further, the pattern film includes a first film and a second film. A first pattern array is built in the first film. The second film is attached on the first film. A second pattern array is built in the second film. The second pattern array is partially electrically connected to the first pattern array. The insulation layer pattern is formed on the pattern film to expose the electrically connected first and second pattern arrays.

Another printed circuit board includes a substrate, a pattern film attached on the substrate and including a first film having a first pattern array and a second film arranged on the first film and having a second pattern array that is partially electrically connected to the first pattern array. The printed circuit board may further include an insulation layer pattern formed on the pattern film to expose the electrically connected first and second pattern arrays.

A semiconductor package in accordance with yet still another embodiment includes a semiconductor chip, a pattern film, a substrate and outer terminals. The pattern film includes a first film and a second film. A first pattern array is built in the first film. The second film is attached on the first film. A second pattern array is built in the second film. The second pattern array is partially electrically connected to the first pattern array and the semiconductor chip. The substrate is electrically connected to the first pattern array. The outer terminals are formed on the substrate.

Another semiconductor package includes a semiconductor chip; a pattern film including a first film having a first pattern array and a second film arranged on the first film, the second film having a second pattern array that is partially electrically connected to the first pattern array and the semiconductor chip; a substrate electrically connected to the first pattern array; and outer terminals formed on the substrate.

According to the embodiments exemplarily described above, the first and the second pattern arrays may be electrically connected to each other by a simple pressurizing process. Thus, a time and a cost for manufacturing the pattern film may be remarkably reduced. As a result, the printed circuit board and the semiconductor package having the pattern film may also be manufactured at a low expense.

Having described embodiments of the present invention, it is noted that modifications and variations can be made by persons skilled in the art in light of the above teachings. It is therefore to be understood that changes may be made in the particular embodiment of the present invention disclosed which is within the scope and the spirit of the invention outlined by the appended claims.

What is claimed is:

1. A pattern film comprising:
a first film having a first pattern array; and
a second film having a second pattern array, wherein the second film is arranged on the first film such that the second pattern array is partially overlapped with the first pattern array.

2. The pattern film of claim 1, wherein the first pattern array comprises first patterns arranged along a lengthwise direction so as to be spaced apart by a first lengthwise interval and arranged along a widthwise direction so as to be spaced apart by a first widthwise interval, wherein the second pattern array comprises second patterns, and wherein at least one of the second patterns is partially overlapped with at least two adjacent ones of the first patterns.

3. The pattern film of claim 2, wherein each of the second patterns is partially overlapped with four adjacent ones of the first patterns.

4. The pattern film of claim 2, wherein the first lengthwise interval and the first widthwise interval are substantially the same, wherein the second patterns are arranged along the lengthwise direction so as to be spaced apart by a second lengthwise interval and wherein the second patterns are arranged along the widthwise direction so as to be spaced apart by a second widthwise interval.

5. The pattern film of claim 4, first and second lengthwise intervals and the first and second widthwise intervals are substantially the same.

6. The pattern film of claim 2, wherein a shape of the first patterns and a shape of the second patterns are substantially the same.

7. The pattern film of claim 6, wherein the shape of the first patterns and the shape of the second patterns is polygonal, substantially circular or elliptical.

8. The pattern film of claim 2, wherein a shape of the first patterns and a shape of the second patterns are different from each other.

9. The pattern film of claim 8, wherein the shape of the first patterns is polygonal and the shape of the second patterns is substantially circular or elliptical.

10. The pattern film of claim 8, wherein the shape of the first natterns is substantially circular and the shape of the second patterns is elliptical.

11. The pattern film of claim 1, wherein the first film and the second film comprise thermoplastic material.

12. The pattern film of claim 11, wherein at least one of the first patterns is electrically isolated from at least one of the second patterns by the thermoplastic material of at least one of the first film and the second film.

13. The pattern film of claim 11, wherein a portion of the first patterns are electrically connected to a portion of the second patterns through the thermoplastic material of at least one of the first film and the second film.

14. The pattern film of claim 13, wherein at least one of the first patterns is electrically isolated from the portion of the first patterns by the thermoplastic material of the first film.

15. A pattern film comprising:
a first film having first patterns arranged along lengthwise and widthwise directions; and
a second film arranged on the first film, the second film having second patterns arranged along the lengthwise and widthwise directions,
wherein each of the second patterns is partially overlapped with at least two adjacent ones of the first patterns.

16. The pattern film of claim 15, wherein the first patterns and the second patterns have a substantially rectangular shape.

17. The pattern film of claim 15, wherein the first film and the second film comprise a deformable insulation material.

18. The pattern film of claim 17, wherein at least one of the first patterns is electrically isolated from at least one of the second patterns by the deformable insulation material of at least one of the first film and the second film.

19. The pattern film of claim 17, wherein a portion of the first patterns are electrically connected to a portion of the second patterns through the thermoplastic material of at least one of the first film and the second film.

20. The pattern film of claim 19, wherein at least one of the first patterns is electrically isolated from the portion of the first patterns by the deformable insulation material of the first film.

21. A method of manufacturing a pattern film, comprising:
preparing a first film having a first pattern array and a second film having a second pattern array;
attaching the second film on the first film, the second pattern array partially overlapped with the first pattern array; and
selectively pressurizing the second film to electrically connect desired portions of the first pattern array and the second pattern array to each other.

22. The method of claim 21, wherein the second film is selectively pressurized using a pattern tool that has a shape corresponding to that of a desired pattern.

23. The method of claim 21, further comprising thermally curing the electrically connected first and second pattern arrays.

24. A printed circuit board comprising:
a substrate;
a pattern film attached on the substrate, the pattern film including a first film having a first pattern array, and a second film arranged on the first film and having a second pattern array that is partially electrically connected to the first pattern array; and
an insulation layer pattern formed on the pattern film to expose the electrically connected first and second pattern arrays.

25. A semiconductor package comprising:
a semiconductor chip;
a pattern film including a first film having a first pattern array, and a second film arranged on the first film, the second film having a second pattern array that is partially electrically connected to the first pattern array and the semiconductor chip;
a substrate electrically connected to the first pattern array; and
outer terminals formed on the substrate.
